(19) United States
(12) Patent Application Publication
(10) Pub. No.: US 2025/0116800 A1
(43) Pub. Date: Apr. 10, 2025

(54) FLEXIBLE MICROPOROUS MULTI-RESONANT PLASMONICS MESHES

(71) Applicant: VIRGINIA TECH INTELLECTUAL PROPERTIES, INC., Blacksburg, VA (US)

(72) Inventors: Aditya Garg, Blacksburg, VA (US); Wei Zhou, Blacksburg, VA (US); Peter J. Vikesland, Blacksburg, VA (US)

(21) Appl. No.: 18/726,271

(22) PCT Filed: Nov. 4, 2022
(86) PCT No.: PCT/US22/48984

§ 371 Date: Jul. 2, 2024

Related U.S. Application Data
(60) Provisional application No. 63/297,001, filed on Jan. 6, 2022.

(51) Int. Cl. G02B 5/00; B82Y 20/00; B82Y 40/00; G03F 7/00; G03F 7/038; G03F 7/36

(52) U.S. Cl. CPC G02B 5/008; B82Y 20/00; B82Y 40/00; G03F 7/0002; G03F 7/0384; G03F 7/36

(57) ABSTRACT

Flexible multi-resonant plasmonic sheets, flexible microporous multi-resonant meshes, and dissolvable template-based hierarchical imprinting fabrication methods are described. A method of manufacture of a flexible microporous multi-resonant plasmonics mesh (MMPM) is described in one example. The method includes depositing alternating metal and insulating layers on a solvent-soluble nanowell array, to form a nanolaminate plasmonic crystal (NLPC) array on the solvent-soluble nanowell array. The method also includes pressing a hydrophobic curable resist over the NLPC array and the solvent-soluble nanowell array, using a watersoluble micropillar array as a working stamp for the pressing, curing the hydrophobic curable resist into a flexible scaffold, and dissolving the water-soluble micropillar array in water. The dissolving exposes a first side of the flexible scaffold, with the solvent-soluble nanowell array supporting a second side of the flexible scaffold. The method also includes dissolving the solvent-soluble nanowell array in a solvent, and separating the solvent-soluble nanowell array from the NLPC array and the flexible scaffold.

### CROSS-REFERENCE TO RELATED APPLICATIONS

This application claims the benefit of and priority to U.S. Provisional Application No. 63/297,001, filed Jan. 6, 2022, titled “Flexible Microporous Multi-resonant Plasmonics Meshes by Hierarchical Micro-Nanoimprinting with Dissolvable Templates,” the entire disclosure of which is hereby incorporated herein by reference.

### STATEMENT REGARDING FEDERALLY SPONSORED RESEARCH OR DEVELOPMENT

This invention was made with government support under Grant No. FA9550-18-1-0328 awarded by the Air Force Office of Scientific Research. This invention was also made with government support under Grant Nos. OISE-1545756, CBET-2029911, and DMR-2139317 awarded by the National Science Foundation. This invention was also made with government support under Grant No. 1542100 awarded by the National Science Foundation. The government bas certain rights in the invention.

### BACKGROUND

Photonics is a branch of optics that involves the generation, detection, and manipulation of light in the form of photons. The field of plasmonics is related to the detection and manipulation of optical signals using metal-dielectric interfaces in the nanometer scale. Following the trend of photonics, the field of plasmonics seeks to miniaturize the optical devices used for the detection and manipulation of optical signals. Plasmonics can be applied to a range of different applications finds uses in optical sensing, microscopy, optical communications, and bio-photonics, among other fields.

### SUMMARY

dissolvable template-based hierarchical imprinting fabrication methods are described herein. A method of manufacture of a flexible microporous multi-resonant plasmonics mesh (MMPM) is described in one example. The method includes depositing alternating metal and insulating layers on a solvent-soluble nanowell array, to form a nanolaminate plasmonic crystal (NLPC) array on the solvent-soluble nanowell array. The method also includes pressing a hydrophobic curable resist over the NLPC array and the solvent-soluble nanowell array, using a water-soluble micropillar array as a working stamp for the pressing, curing the hydrophobic curable resist into a flexible scaffold, and dissolving the water-soluble micropillar array in water. The dissolving exposes a first side of the flexible scaffold, with the solvent-soluble nanowell array supporting a second side of the flexible scaffold. The method also includes dissolving the solvent-soluble nanowell array in a solvent, and separating the solvent-soluble nanowell array from the NLPC array and the flexible scaffold.

In other aspects, the method also includes forming a micropillar array master over a substrate with a photoresist using photolithography, forming a hydrophobic microwell array mold from hydrophobic perfluoropolyether (PFPE) using the micropillar array master, and forming the water-soluble micropillar array from polyacrylic acid (PAA) using the hydrophobic microwell array mold. Additionally, the method can also include forming a nanowell array master in silicon, forming a hydrophobic nanopillar array mold from hydrophobic perfluoropolyether (PFPE) using the nanowell array master, and forming the solvent-soluble nanowell array from poly (methyl methacrylate) (PMMA) using the hydrophobic nanopillar array mold.

In other aspects, the method can also include etching flexible scaffold to expose plasmonic nanogap hotspots of NLPCs in the NLPC array. The etching can include reactive ion etching (RIE) in a plasma of oxygen and carbon tetrafluoride (CF₄). The etching can also include buffered oxide etching. In other aspects, the method can include forming voids in the hydrophobic curable resist during the pressing, with pillars of the water-soluble micropillar array. The voids open to micropores in the NLPC array and the flexible scaffold, after the dissolving and the separating. Further, depositing the alternating metal and insulating layers can include depositing alternating layers of gold and silicon dioxide.

MMPMs are described in other embodiments. An example MMPM includes a flexible scaffold, a NLPC array on the flexible scaffold, and micropores extending through the flexible scaffold and the NLPC array. The flexible scaffold can include a UV-cured hydrophobic resist, and the micropores can include a periodic array of micropores. The micropores can include shapes other than four-sided shapes, such as circular, oval, fan, “S,” “L,” serpentine, and other shapes. In other aspects, the NLPC array can include a two-tier NLPC array.

A method of manufacture of a flexible multi-resonant plasmonics array is described in other embodiments. The method can include depositing alternating metal and insulating layers on a solvent-soluble nanowell array, to form an NLPC array on the solvent-soluble nanowell array. The method can also include pressing a hydrophobic curable resist over the NLPC array and the solvent-soluble nanowell array, using a water-soluble sheet for the pressing, and curing the hydrophobic curable resist into a flexible scaffold. The method can also include dissolving the water-soluble sheet in water, and dissolving the solvent-soluble nanowell array in a solvent. The method can also include separating the solvent-soluble nanowell array from the NLPC array and the flexible scaffold.

### BRIEF DESCRIPTION OF THE DRAWINGS

Many aspects of the present disclosure can be better understood with reference to the following drawings. The components in the drawings are not necessarily drawn to scale, with emphasis instead being placed upon clearly illustrating the principles of the disclosure. In the drawings, like reference numerals designate corresponding parts throughout the several views.

FIG. 1 illustrates an example array of nanolaminate plasmonic crystals (NLPCs) according to certain aspects of the embodiments.

FIG. 2A illustrates an example flexible microporous multi-resonant plasmonics mesh (MMPM) according to certain aspects of the embodiments.

FIG. 2B illustrates example micropore shapes and geometries for MMPMs according to certain aspects of the embodiments.

FIG. 3 illustrates an example method of fabricating multi-resonant plasmonics array structures and transferring the array structures to flexible scaffolds according to certain aspects of the embodiments.

FIG. 4 illustrates a cross-sectional view of a representative hydrophobic nanopillar array mold and solvent-soluble poly(methyl methacrylate) (PMMA) sheet according to certain aspects of the embodiments.

FIG. 5 illustrates a cross-sectional view of a representative nanowell array and NLPCs formed on or over the nanowell array according to certain aspects of the embodiments.

FIG. 6 illustrates a cross-sectional view of a representative poly(acrylic acid) (PAA) sheet, UV-curable resist, NLPC array, and nanowell array according to certain aspects of the embodiments.

FIG. 7 illustrates a cross-sectional view of a cured resist, NLPC array, and nanowell array according to certain aspects of the embodiments.

FIG. 8 illustrates a cross-sectional view of an example flexible, mechanically-stabilized NLPC array according to certain aspects of the embodiments.

FIG. 9 illustrates a cross-sectional view of the flexible NLPC array, after etching to expose the hotspots in the NLPC array, according to certain aspects of the embodiments.

FIG. 10 illustrates an example method of fabricating MMPMs according to certain aspects of the embodiments.

FIG. 11 illustrates a cross-sectional view of a representative hydrophobic microwell array mold, water-soluble PAA sheet, and polyethylene terephthalate (PET) sheet according to certain aspects of the embodiments.

FIG. 12 illustrates a cross-sectional view of a representative micropillar array and PET sheet according to certain aspects of the embodiments.

FIG. 13 illustrates a cross-sectional view of a representative micropillar array of PAA, UV-curable resist, NLPC array, and nanowell array according to certain aspects of the embodiments.

FIG. 14 illustrates a cross-sectional view of a cured resist, NLPC array, and nanowell array according to certain aspects of the embodiments.

FIG. 15 illustrates a cross-sectional view of the flexible, mechanically-stabilized NLPC array, after bottom-side etching to expose the hotspots in the NLPC array, according to certain aspects of the embodiments.

FIG. 16 illustrates a cross-sectional view of an example flexible MMPM according to certain aspects of the embodiments.

FIG. 17 illustrates a cross-sectional view of an example flexible MMPM after top-side etching according to certain aspects of the embodiments.

### DETAILED DESCRIPTION

Plasmonic nanoantenna arrays based on metal nanostructures can support surface plasmon resonances. The plasmon resonances enhance light-matter interactions at the nanoscale for bio-interfaced spectroscopy, sensing, actuation, and other uses. For example, plasmonic nanoantennas can enable surface-enhanced Raman spectroscopy (SERS) for the sensitive detection of biochemical analytes and in-situ molecular profiling of living biological systems. Plasmonic nanoantennas modified with specific receptors can also achieve refractive index (RI) sensing of target biomolecules in biological environments. Plasmonic nanoantennas can also serve as nanolocalized photothermal heat sources, to induce cell membrane optoporation for drug delivery and the excitation of neurons. Thus, the development of microporous mesh plasmonic devices offers new opportunities for bio-interfaced optical sensing and actuation applications, among others.

Some plasmonic nanoantennas optimize single-resonant optical characteristics within one wavelength band. These nanoantennas are sufficient for applications based on single-photon and single-band processes. For emerging applications in nanophotonics involving multiphoton processes, it may be necessary to use multi-resonant plasmonic nanostructures. Multi-resonant plasmonic nanostructures can simultaneously enhance light-matter interactions in several resonant spectral bands. For example, the multi-resonant plasmonic enhancement of multi-photon excitation and emission transitions can boost second harmonic generation (SHG) or up-conversion photoluminescence (UCPL) signals, which are useful for deep-tissue optical sensing and imaging. Multi-resonant plasmonic nanostructures also enable wavelength-multiplexed multi-modal optical operations at the nano-bio interface. A general approach to construct multi-resonant plasmonic devices is to assemble plasmonic resonators from a number of building blocks, each positioned within a close distance of each other. The optical coupling between the elementary modes of the building blocks can result in multiple hybridized plasmonic modes with spatial overlaps at different wavelengths.

In the field of plasmonic nanoantenna arrays, flexible, mesh-like microporous devices offer biocompatibility advantages for interfacing with cell networks and tissues, biomedical sensing, biomedical actuation, and other applications. Flexible microporous devices having relatively low elastic moduli and high permeability to nutrients and oxygen are better candidates for biocompatibility. Many microporous mesh devices employ arrays of electrical components, including microelectrodes and nanoscale transistors. Such electrical mesh devices can serve as inflammation-free epidermal sensors for long-term health monitoring, sensor-array scaffolds for in-vitro drug response monitoring in 3D cell culture models, and minimally invasive brain probes for in-vivo electrical recording in animals. As compared to electrical mesh devices, there has been relatively little work on optical mesh devices, such as optical mesh devices based on dense plasmonic nanoantenna arrays for bio-interfacing applications.

Microporous mesh plasmonic devices have the potential to combine the biocompatibility of microporous polymeric meshes with the capabilities of plasmonic nanostructures. Microporous mesh plasmonic devices can enhance light-matter interactions, at the nanoscale level, for bio-interfaced optical sensing and actuation, among other useful applications. It has been challenging, however, to integrate uniformly structured plasmonic devices at scale. It has also been challenging to fabricate uniformly structured plasmonic devices into microporous meshes at scale. The scalable integration of dense and uniformly structured plasmonic hotspot arrays with microporous polymeric meshes is challenging, in part, due to the processing incompatibility of conventional nanofabrication methods with flexible microporous substrates.

Multi-resonant plasmonic devices have been formed using top-down fabrication methods, such as electron-beam lithography (EBL), focused ion beam (FIB), deep-ultraviolet lithography (DUVL), laser-direct-writing (LDW), and nanoimprint lithography (NIL). Despite research efforts, the existing methods of forming multi-resonant plasmonic devices face challenges, such as relatively low hotspot density, weak excitability of multipolar modes, and lack of scalable nanofabrication methods compatible with flexible microporous substrates. Similar challenges have been encountered in the fabrication of microporous mesh plasmonic devices.

According to aspects of the embodiments, dissolvable template-based hierarchical imprinting approaches are described to create mechanically-stabilized arrays or sheets of nanolaminate plasmonic crystals (NLPCs). The stabilized NLPC arrays include optically-coupled nanodome and nanohole multi-resonant sub-systems. The approach can also be relied upon to transfer (e.g., move and place) arrays or sheets of NLPCs onto a range of surfaces or substrates, including flexible surfaces or substrates, such as flexible membranes, textiles, and scaffolds. The result is a flexible NLPC array, having a range of applications in plasmonics.

A related dissolvable template-based hierarchical micro-/nano-imprinting approach can also be relied upon to create microporous multi-resonant plasmonic meshes (MMPMs), by the transfer of the stabilized arrays of NLPCs onto polymeric micro-porous scaffolds using imprint lithography. Thus, new dissolvable template-based approaches are described to form arrays of NLPCs, to transfer the arrays of NLPCs onto flexible membranes, textiles, and scaffolds, and to form flexible MMPMs. The nanofabrication of the arrays of NLPCs and MMPMs is achieved using a hierarchical lithography approach using dissolvable polymeric templates.

By supporting multiple, spatially-overlapped plasmonic modes, the transferable NLPC arrays and MMPMs facilitate multi-resonant plasmonic enhancement of SHG, third-harmonic generation (THG), and UCPL signal emissions under fs laser pulses over a wide excitation wavelength range. The transferable NLPC arrays MMPMs can also support dense and uniform SERS hotspot arrays for in-situ spatiotemporal molecular profiling of bacterial biofilm formation and growth, among other applications. The MMPMs can serve as broadband, non-linear, nano-plasmonic devices. The MMPMs can also function as bio-interfaced SERS mesh sensors. Such SERS mesh sensors can enable in-situ spatiotemporal molecular profiling of bacterial biofilm activity, among other uses. The MMPMs can also be used in bio-interfaced optical sensing and actuation applications, such as inflammation-free epidermal sensors in conformal contact with skin, combined tissue-engineering and biosensing scaffolds for in-vitro 3D cell culture models, and minimally invasive implantable probes for long-term disease diagnostics and therapeutics.
dissolvable template-based hierarchical imprinting fabrication methods are described herein. A method of manufacture of a flexible microporous multi-resonant plasmonics mesh (MMPM) is described in one example. The method includes depositing alternating metal and insulating layers on a solvent-soluble nanowell array, to form a nanolaminate plasmonic crystal (NLPC) array on the solvent-soluble nanowell array. The method also includes pressing a hydrophobic curable resist over the NLPC array and the solvent-soluble nanowell array, using a water-soluble micropillar array as a working stamp for the pressing, curing the hydrophobic curable resist into a flexible scaffold, and dissolving the water-soluble micropillar array in water. The dissolving exposes a first side of the flexible scaffold, with the solvent-soluble nanowell array supporting a second side of the flexible scaffold. The method also includes dissolving the solvent-soluble nanowell array in a solvent, and separating the solvent-soluble nanowell array from the NLPC array and the flexible scaffold.

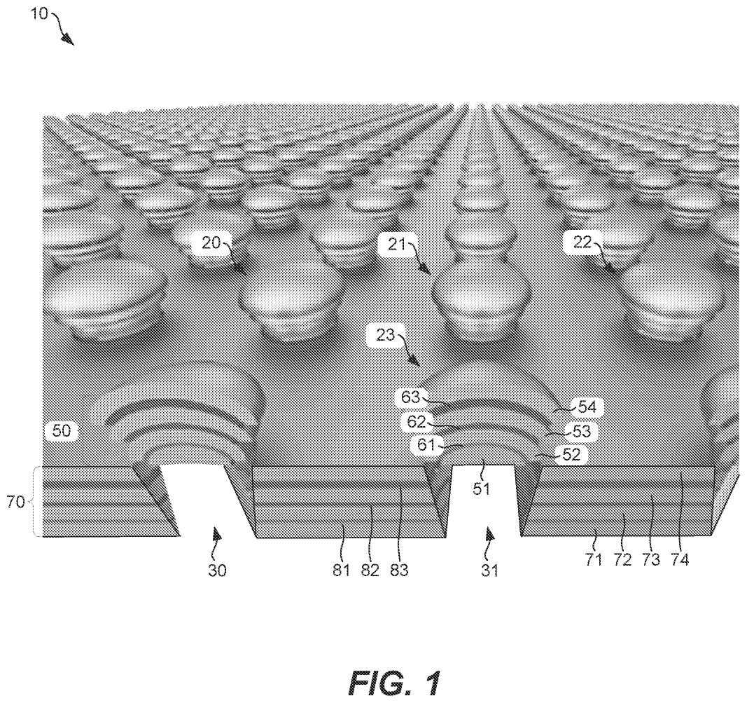

Turning to the drawings, FIG. 1 illustrates an example array 10 of NLPCs (also “array 10” or “NLPC array 10”) according to certain aspects of the embodiments. The two-tier configuration of the array 10 supports a number of spatially overlapped and highly-excitable hybridized plasmonic modes under free-space light illumination. The array 10 is provided as a representative example of an array of NLPCs. The array 10 is not drawn to any particular scale or size, and the embodiments are not limited to any particular type of NLPC array.

As one example, the array 10 can be similar to those described in the article titled “Two-Tier Nanolaminate Plasmonic Crystals for Broadband Multiresonant Light Concentration with Spatial Move Overlap,” published in Volume 9, Issue 10, of the Advanced Optical Materials journal, dated May 19, 2021, by Seied Ali Safiabadi Tali, Junyeob Song, Wonil Nam, and Wei Zhou (also found at https://doi.org/10.1002/adom.202001908), the entire contents of which is hereby incorporated herein by reference. In that sense, the array 10 can support a number of spatially overlapped and highly-excitable hybridized plasmonic modes under free-space light illumination, as well as the related applications of those plasmonic modes. However, the array 10 can also vary as compared to those described in the above-identified article, based on the use of different metal layers, different insulating layers, different nanodome and nanohole sizes, pitch spacings, and other characteristics.

The array 10 includes a number of optically-coupled nanodome and nanohole multi-resonant sub-systems. As shown in FIG. 1, the array 10 includes optically-coupled nanodomes 20-23, among others, and nanoholes 30 and 31, among others. The nanodomes 20-23 are optically coupled with the nanoholes 30 and 31, to form a multi-resonant plasmonic device. In the example shown, each of the nanodomes 20-23 is formed by a materials stack 50, and each of the nanoholes 30 and 31 is formed among a materials stack 70. The materials stack 50 includes a multi-layered metal-insulator-metal stack of materials, and the materials stack 70 includes a multi-layered metal-insulator-metal stack of materials. The metal and insulating materials in the materials stack 50 can be the same as the metal and insulating materials in the materials stack 70, as described herein.

The materials stack 50 includes metal layers 51-54 and insulating layers 61-63. Particularly, from bottom to top, the materials stack 50 includes the metal layer 51, the insulating layer 61 over the metal layer 51, the metal layer 52 over the insulating layer 61, the insulating layer 62 over the metal layer 52, the metal layer 53 over the insulating layer 62, the insulating layer 63 over the metal layer 53, and the metal layer 54 over the insulating layer 63. Similarly, the materials stack 70 includes metal layers 71-74 and insulating layers 81-83. Particularly, from bottom to top, the materials stack 70 includes the metal layer 71, the insulating layer 81 over the metal layer 71, the metal layer 72 over the insulating layer 81, the insulating layer 82 over the metal layer 72, the metal layer 73 over the insulating layer 82, the insulating layer 83 over the metal layer 73, and the metal layer 74 over the insulating layer 83.

The metal layers 51-54 and 71-74 can be formed from gold (Au), silver (Ag), or copper (Cu), although other metals can be used in some cases. The metal layers 51-54 and 71-74 can be formed at a thickness between 8-12 nm, for example, including thicknesses of 8 nm, 9 nm, 10 nm, 11 nm, or 12 nm, although other thicknesses can be used. The metal layers 51-54 and 71-74 can also include thinner layers of titanium (Ti) between the Au, Ag, or Cu layers (i.e., on the top, the bottom, or both the top and bottom of the Au, Ag, or Cu layers) and the insulating layers 61-63 and 81-83, to help with adhesion of the metal and insulating layers. The layers of titanium can be between 0.5-0.9 nm in thickness, including thicknesses of 0.5 nm, 0.6 nm, 0.7 nm, 0.8 nm, or 0.9 nm, although other thicknesses can be used. The insulating layers 61-63 and 81-83 can be formed from silicon dioxide (SiO₂) or titanium dioxide (TiO₂), although dielectric other insulators can be used in some cases. The insulating layers 61-63 can be formed at a thickness between 8-12 nm, for example, including thicknesses of 8 nm, 9 nm, 10 nm, 11 nm, or 12 nm, although other thicknesses can be used. In one example, the insulating layers 61-63 can vary in thickness. For example, the insulating layer 61 can be 8 nm in thickness, the insulating layer 62 can be 10 nm in thickness, and the insulating layer 63 can be 12 nm in thickness.

In other examples, the nanodomes 20-23 and the nanoholes 30 and 31 in the array 10 of NLPCs can be formed with fewer or greater metal and insulating layers. As examples, arrays of NLPCs can be formed having 1 metal layer (1ML and no insulating layers), 2 metal layers (2MLs), 3 metal layers (3MLs), 4 metal layers (4MLs), or more metal layers, with insulating layers separating the metal layers.

Multi-resonant plasmonic devices similar to the array 10 have been formed using top-down fabrication methods, such as electron-beam lithography (EBL), focused ion beam (FIB), deep-ultraviolet lithography (DUVL), laser-direct-writing (LDW), and nanoimprint lithography (NIL). However, the existing methods of forming multi-resonant plasmonic devices face a number of challenges, such as relatively low hotspot density, weak excitability of multipolar modes, and lack of scalable nanofabrication methods compatible with flexible microporous substrates. It has also been challenging to integrate uniformly structured plasmonic devices at scale and to fabricate uniformly structured plasmonic devices into microporous meshes at scale. The scalable integration of dense and uniformly structured plasmonic arrays with microporous polymeric meshes is challenging, in part, due to the processing incompatibility of conventional nanofabrication methods with flexible microporous substrates.

In the context described above, a number of dissolvable template-based hierarchical imprinting approaches are described to nanofabricate mechanically-stabilized arrays or sheets of NLPCs. The approaches can be relied upon to transfer (e.g., move and place) arrays or sheets of NLPCs onto a range of surfaces or substrates, including flexible surfaces or substrates, such as flexible membranes, textiles, and scaffolds. The result is a flexible NLPC array, having a range of applications in plasmonics. Related dissolvable template-based hierarchical micro-/nano-imprinting approaches can also be relied upon to create microporous multi-resonant plasmonic meshes (MMPMs), by the transfer of the stabilized arrays of NLPCs onto polymeric micro-porous scaffolds using imprint lithography. These and other aspects of the embodiments are described below.

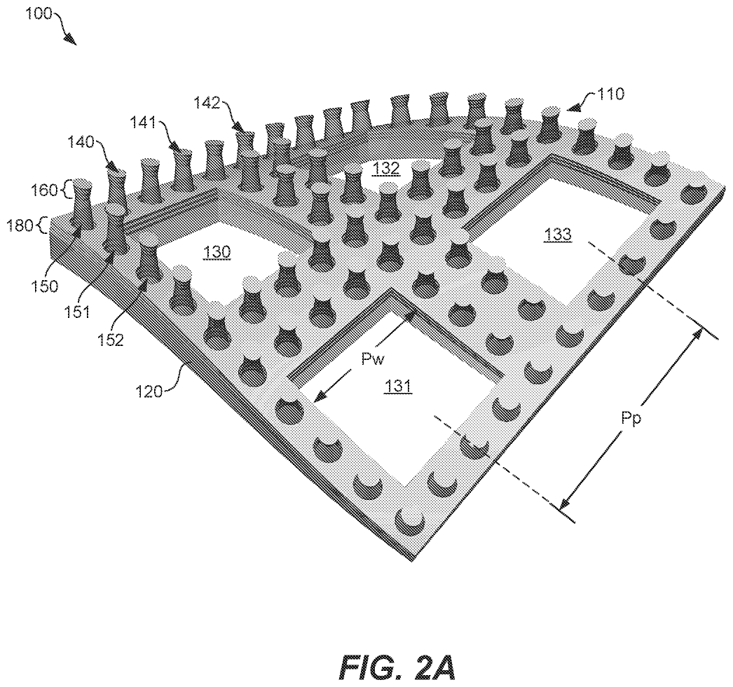

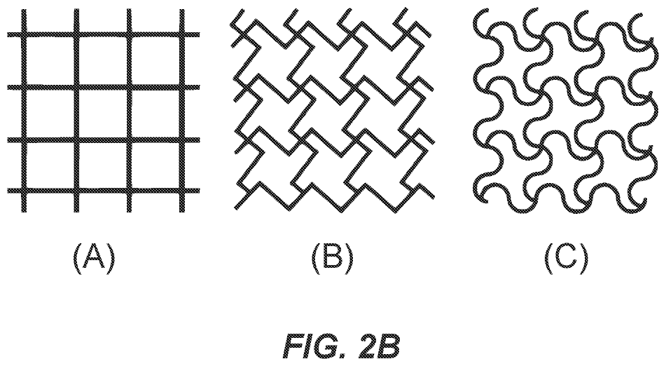

FIG. 2A illustrates an example flexible MMPM 100 according to certain aspects of the embodiments. The MMPM 100 includes an array 110 of NLPCs (also “array 110” or “NLPC array 110”) on or over a flexible polymeric micro-porous scaffold 120 (also “scaffold 120”). The MMPM 100 is illustrated in FIG. 2A as a representative example of an array of NLPCs on a flexible polymeric micro-porous scaffold. The MMPM 100 is not drawn to any particular scale or size, and the embodiments are not limited to any particular type of MMPM 100. In practice, the dissolvable template-based hierarchical imprinting approaches described herein can be relied upon to fabricate MMPMs having a range of sizes and shapes. The MMPMs can also have different numbers, sizes, shapes, and positions of pores, as described below.

The MMPM 100 includes a number of pores, openings, or apertures, such as the micropores 130-133. The micropores 130-133 extend through all the layers of the array 110 and the scaffold 120, to permit fluids, cells, and other materials to extend into and through the micropores 130-133, for analysis using the MMPM 100. The NLPC array 110 of the MMPM 100 includes a number of optically-coupled nanodome and nanohole multi-resonant sub-systems. As shown in FIG. 2A, the array 110 includes optically-coupled nanodomes 140-142, among others, and nanoholes 150-152, among others. The nanodomes 140-142 are optically coupled with the nanoholes 150-152, to form a multi-resonant plasmonic device. Each of the nanodomes 140-142 is formed by a materials stack 160, and each of the nanoholes 150-152 is formed among a materials stack 180. The materials stack 160 includes a multi-layered metal-insulator-metal stack of materials, and the materials stack 180 includes a multi-layered metal-insulator-metal stack of materials, both of which are described in additional detail below. The metal and insulating materials in the materials stack 160 can be the same as the metal and insulating materials in the materials stack 180, as described below.

The micropores 130-133 can be omitted from the example shown in FIG. 2A in some cases. That is, the NLPC array 110 can be on or over the flexible scaffold 120, without the micropores 130-133 through the NLPC array 110 and the flexible scaffold 120. The MMPM 100 shown in FIG. 2A would be similar in that case to the NLPC array 10 shown in FIG. 1, but on or over the flexible scaffold 120. Such an NLPC array 110 (i.e., without the micropores 130-133) is one example of a flexible multi-resonant array structure or device according to aspects of the embodiments.

The micropores 130-133 are shown as square pores in FIG. 2A, although other shapes can be relied upon. Other pore shapes and geometries for MMPMs are described below with reference to FIG. 2B. The micropores 130-133 can be sized to have a pore width “Pw” in the micrometer range, such as between 1-100 μm, including all the widths between 1 μm and 100 μm in increments of 1 μm (e.g., 1 μm, 2 μm, 3 μm, . . . 99 μm, and 100 μm), although some smaller and larger pore sizes can be used in some cases. As measured from the centers of any two micropores, the micropores 130-133 can be spaced at a periodicity or pitch “Pp” between 3-1000 μm, including all the pitch spacings between 3 μm and 1000 μm in increments of 1 μm, although other pitches be used.

FIG. 2B illustrates example micropore shapes and geometries for MMPMs according to certain aspects of the embodiments. In (A), a square micropore shape, similar to that used for the micropores 130-133 in FIG. 2A, is shown. Other four-sided shapes can be used, including rectangle and rhombus shapes. In practice, shapes with sharp comers can result in micropores having rounded comers or edges, due to the flexible nature of the materials from which the scaffolds are formed. The shapes of the micropores in MMPMs are not limited to four-sided shapes, however, and shapes other than four-sided shapes can be implemented. As examples, circular, oval, and other shapes of micropores can be used. Additionally, in (B), a fan shape with squared corners is shown as another shape for micropores in MMPMs according to the embodiments. In (C), a fan shape with rounded corners is shown. Other shapes can also be used, including “S,” “L,” serpentine, and other shapes.

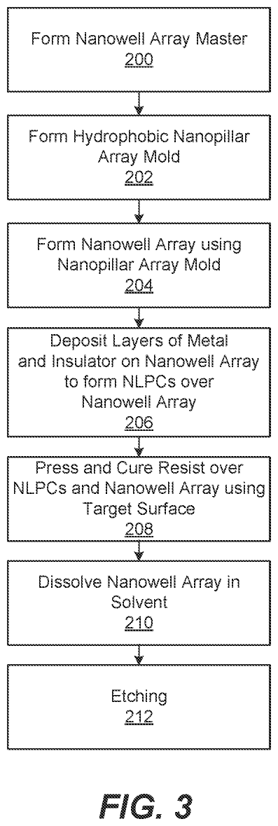

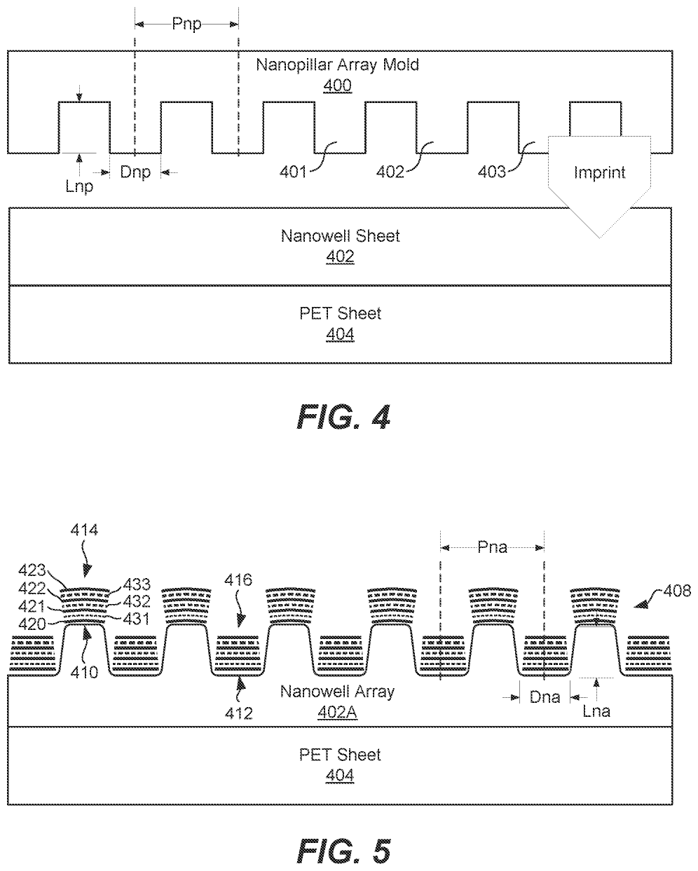

New methods for fabrication of flexible multi-resonant NLPC arrays and MMPMs, such as those described above with reference to FIG. 2A, are described below. FIG. 3 illustrates an example method of fabricating multi-resonant plasmonics array structures and transferring the array structures to flexible scaffolds. The method includes a dissolvable template-based hierarchical imprinting approach. The particular sequence of steps illustrated in FIG. 3 can vary as compared to that shown. For example, one or more of the steps can be rearranged in order, one or more of the steps can be omitted, and one or more additional steps can be added to the process flow shown. Additionally, two or more of the steps can be performed concurrently or, at least in part, at the same time. Although the individual steps in FIG. 3 are described with reference to FIGS. 4-9, the illustrations in FIGS. 4-9 are only representative and the process can be applied to form other structures similar to those shown in FIGS. 4-9.

At step 200, the process includes forming a nanowell array master. The nanowell array master can be relied upon to form a nanopillar array mold at step 202, as described below. The nanowell array master can be formed from a silicon substrate, for example, or substrate of other material(s). As one example, the nanowell array master can be formed by etching a silicon substrate, such that the silicon substrate includes an array of wells. The nanowell array master can thus be embodied as a silicon substrate having a top surface, with an array of wells extending down into the silicon substrate from the top surface of the substrate. Each of the wells can be cylindrical in shape (i.e., having a circular bottom well surface), as one example, although wells having alternate shapes, such as wells having oval, square (or square with rounded comers), rectangular (or rectangular with rounded corners), or other shapes can be formed in some cases. The substrate can range in size, and typical wafer sizes can be used. Example wafer sizes include 100 mm, 125 mm, 150 mm, 200 mm, 300 mm, and 450 mm, and other sizes can be used. Starting from step 200, the flexible multi-resonant NLPC arrays and MMPMs described herein can be formed about as large as the size of the nanowell array master formed at step 200.

The pitch or periodicity of the wells (i.e., as measured from a center of each well) in the substrate, in both directions of the array, can range among the embodiments. Example pitches or spacings among the wells can range from 100 nm to 2 μm, including all the pitch spacings between 100 nm to 2 μm in increments of 1 nm. The diameter of each well can range from 40 nm to 600 nm, including all the diameter spacings between 40 nm to 600 nm in increments of 1 nm. The depth of each well can range from 100 nm to 1 μm, including all the depth spacings between 100 nm to 1 μm in increments of 1 nm. In some cases, each well in the array of wells can have the same diameter and depth. However, in some cases, groups or sub-arrays of wells in the array can have different diameters, depths, and pitch spacings. The precision of the pitch, diameter, depth, and related spacings will depend on the precision of the etching or related technique used to form the wells, as would be understood by a person of skill.

At step 202, the method includes forming a nanopillar array mold using the nanowell array master. The nanopillar array mold can be a hydrophobic nanopillar array mold. As one example, the nanopillar array mold can be formed from a UV-curable hydrophobic perfluoropolyether (PFPE) using UV nanoimprint lithography. To form the mold, the nanowell array master can be spin coated or drop dispensed with Fluorolink® MD700, which is a UV-curable PFPE hydrophobic compound, for example, or similar UV-curable hydrophobic PFPE. Imprinting the nanopillar array mold can then proceed by pressing the PFPE hydrophobic compound with a transparent template (e.g., a quartz glass or other working stamps), and the imprinted PFPE cured by UV-light exposure to cross-link the PFPE.

After it is applied and pressed over the nanowell array master, the PFPE can be cured by UV light for 3 minutes under 2 bar of pressure applied top-down on the working stamp. This can be followed by another round of UV curing for 3 minutes under a vacuum and a post-annealing step at 100° C. for 45 minutes, or other periods of time, to the extend needed. Other curing or cross-linking approaches can be relied upon. After curing, the hydrophobic nanopillar array mold can be lifted off the nanowell array master and used in later process steps.

A cross-sectional view of a representative hydrophobic nanopillar array mold 400, formed in step 202, is illustrated in FIG. 4. The nanopillar array mold 400 is representative and not drawn to scale. Additionally, FIG. 4 only illustrates only a portion of the nanopillar array mold 400. The nanopillar array mold 400 includes a number of nanopillars 401-403, among others, in an array of nanopillars. The nanopillars are formed at a pitch “Pnp,” have a diameter “Dnp,” and have a length “Lpn.” The pitch “Pnp,” diameter “Dnp,” and length “Lnp” are determined by the pitch, diameter, and depth dimensions corresponding to the nanowells in the nanowell array master, as described above.

At step 204, the process includes forming a nanowell array using the nanopillar array mold that was formed at step 202. The nanowell array can be a solvent-soluble nanowell array formed from poly (methyl methacrylate) (PMMA) in one example. In that case, a sheet of solvent-soluble PMMA is formed over a sheet of polyethylene terephthalate (PET) placed over a substrate. The PET sheet can be relied upon as a transferring carrier for the PMMA sheet. As one example, a 20% weight for weight (w/w) solution of PMMA in anisole can be prepared and spin-coated on the sheet of PET. The PMMA can have an average molecular weight of 15,000 grams per mole (g/mol), for example, although other types of PMMA can be used. The PMMA can be product number 200336 (CAS number 9011-14-7) of SIGMA-ALDRICH®, as one example. After sufficient mixing, the solution of PMMA in anisole can be spin coated on the sheet of PET at 3000 rpm, for 30 seconds, for example, followed by heating at 150° C. for 3 minutes to evaporate the anisole solvent. The resulting PMMA sheet can be formed into the nanowell array by thermal nanoimprint lithography, as described below. An example nanowell sheet 402 is shown in FIG. 4 over a PET sheet or layer 404.

In another example, the nanowell array can be a water-soluble nanowell array formed from polyacrylic acid (PAA). In that case, a 50% w/w solution of PAA in methanol can be prepared and spin-coated on a sheet of PET. The PAA can have an average molecular weight of 1,800 g/mol, for example, although other types of PAA can be used. The PAA can be product number 323667 (CAS number 9003-01-4) of SIGMA-ALDRICH®, as one example. The solution of PAA in methanol can be spin coated on the sheet of PET at 3000 rpm, for 30 seconds, for example, followed by heating to evaporate the methanol solvent. The resulting PAA sheet can be formed into the nanowell array by thermal nanoimprint lithography, as described below. An example nanowell sheet 402, which can be the PMMA sheet or the PAA sheet, is shown in FIG. 4 over a PET sheet or layer 404. The nanowell array is not limited to being formed from PMMA or PAA sheets, and the nanowell array can also be formed from materials similar to PMMA or PAA in some cases.

Next, the solvent-soluble nanowell array of PMMA or the water-soluble nanowell array of PAA is formed by thermal nanoimprint lithography of the PMMA sheet or the PAA sheet by the nanopillar array mold. Referring to FIG. 4 as an example, the nanopillar array mold 400 is imprinted (e.g., brought into contact with) into the nanowell sheet 402. The nanopillar array mold 400 is pressed into the nanowell sheet 402 under pressure and temperature. An example imprint time, pressure, and temperature are 10 minutes, 6 bar, and 170° C., respectively, although other imprint times, pressures, and temperatures (e.g., temperatures above the glass transition temperature of the PMMA or PAA) can be used. The nanopillar array mold 400 is then separated from the nanowell sheet 402 (e.g., by lift off). The nanowell sheet 402 is thus molded into a solvent-soluble nanowell array of PMMA or a water-soluble nanowell array of PAA by the thermal nanoimprint lithography. An example nanowell array is shown as the nanowell array 402A in FIG. 5.

The wells in the nanowell array 402A are formed at a pitch “Pna,” have a diameter “Dna,” and have a depth “Lna.” The pitch “Pna,” diameter “Dna,” and length “Lna” are determined by the pitch, diameter, and depth of the nanopillars in the nanopillar array mold 400, as described above. Example pitches or spacings “Pna” among the wells can range from 100 nm to 2 μm, including all the pitch spacings between 100 nm to 2 μm in increments of 1 nm. The diameter “Dna” of each well can range from 40 nm to 600 nm, including all the diameter spacings between 40 nm to 600 nm in increments of 1 nm. The depth “Lna” of each well can range from 100 nm to 1 μm, including all the depth spacings between 100 nm to 1 μm in increments of 1 nm. The precision of the pitch, diameter, depth, and related spacings will depend on the precision to which the nanopillar array mold 400 is formed, as well as the effectiveness of the thermal nanoimprint lithography used to form it, as would be understood by a person of skill.

At step 206, the process includes depositing alternating metal and insulating layers on or over the nanowell array. The deposition of the alternating metal and insulating layers forms an array of NLPCs on the nanowell array. The metal and insulating layers can be formed as thin films on the nanowell array by electron-beam physical vapor deposition (EBPVD) or other suitable materials deposition processing techniques. The thicknesses of the metal and insulating layers can be selected to achieve multi-resonant plasmonic responses across a broad visible to near-infrared (Vis-NIR) range.

Referring to FIG. 5, the stack of alternating metal and insulating layers is deposited on the top surface 410 of the nanowell array 402A, and the alternating metal and insulating layers can be continuous and unbroken over this top surface 410 (i.e., considering that a cross-section is shown in FIG. 5). The stack is also formed on the surfaces within the openings, holes, or wells formed in the nanowell array 402A, such as the surface 412 at the bottom of one of the wells. The openings, holes, or wells are formed during the thermal nanoimprinting at step 204, based on the imprints left by the nanopillars 401-403 (see FIG. 4), among others. The stacks metal and insulating layers are separated from each other in each of the holes or wells.

An example materials stack 414 is shown on the top surface 410 of the nanowell array 402A, and an example materials stack 416 is shown on the surface 412 within an opening in the nanowell array 402A. The materials stack 414 on the top surface 410 of the nanowell array 402A will be similar to the materials stack 180 shown in FIG. 2A, as an example, at the end of the fabrication process. Additionally, at the end of the fabrication process, the materials stack 416 will be similar to the materials stack 160 shown in FIG. 2A. The alternating metal and insulating layers form an NLPC array 408 on the nanowell array 402A. The materials stacks 414 and 416 are not drawn to scale or size in FIG. 5. Instead, the sizes of the materials stacks 414 and 416 are exaggerated, so that the individual layers in the stacks can be better illustrated. The materials stacks 414 and 416 are shown as being relatively smaller (i.e., not expanded) in other figures of the drawings.

The materials stack 414 includes metal layers 420-423 and insulating layers 431-433. In other examples, the materials stacks 414 and 416 can include fewer or greater metal and insulating layers. Arrays of NLPCs can be formed having 1 metal layer (1ML and no insulating layers), 2 metal layers (2MLs), 3 metal layers (3MLs), 4 metal layers (4MLs), or more metal layers, with insulating layers separating the metal layers.

In the example shown in FIG. 5, from bottom to top, the materials stack 414 includes the metal layer 420, the insulating layer 431 over the metal layer 420, the metal layer 421 over the insulating layer 431, the insulating layer 432 over the metal layer 421, the metal layer 422 over the insulating layer 432, the insulating layer 433 over the metal layer 422, and the metal layer 423 over the insulating layer 433. The materials stack 416 includes metal and insulating layers that are the same as those in the materials stack 414, and the materials stack 416 is formed at the same time and using the same deposition steps as the materials stack 414.

The metal layers 420-423 can be formed as layers of Au, Ag, or Cu, although other metals can be used in some cases. The metal layers 420-423 can be formed at a thickness between 8-12 nm, for example, including thicknesses of 8 nm, 9 nm, 10 nm, 11 nm, or 12 nm, although other thicknesses can be used. The metal layers 420-423 can also include thinner layers of Ti between the Au, Ag, or Cu layers (i.e., on the top, the bottom, or both the top and bottom of the Au, Ag, or Cu layers) and the insulating layers 431-433, to help with adhesion of the metal and insulating layers. The layers of titanium can be between 0.5-0.9 nm in thickness, including thicknesses of 0.5 nm, 0.6 nm, 0.7 nm, 0.8 nm, or 0.9 nm, although other thicknesses can be used.

The insulating layers 431-433 can be formed from silicon dioxide (SiO₂) or titanium dioxide (TiO₂), although other dielectric insulators can be used in some cases. The insulating layers 431-433 can be formed at a thickness between 8-12 nm, for example, including thicknesses of 8 nm, 9 nm, 10 nm, 11 nm, or 12 nm, although other thicknesses can be used. In one example, the insulating layers 431-433 can vary in thickness. For example, the insulating layer 431 can be 8 nm in thickness, the insulating layer 432 can be 10 nm in thickness, and the insulating layer 433 can be 12 nm in thickness.

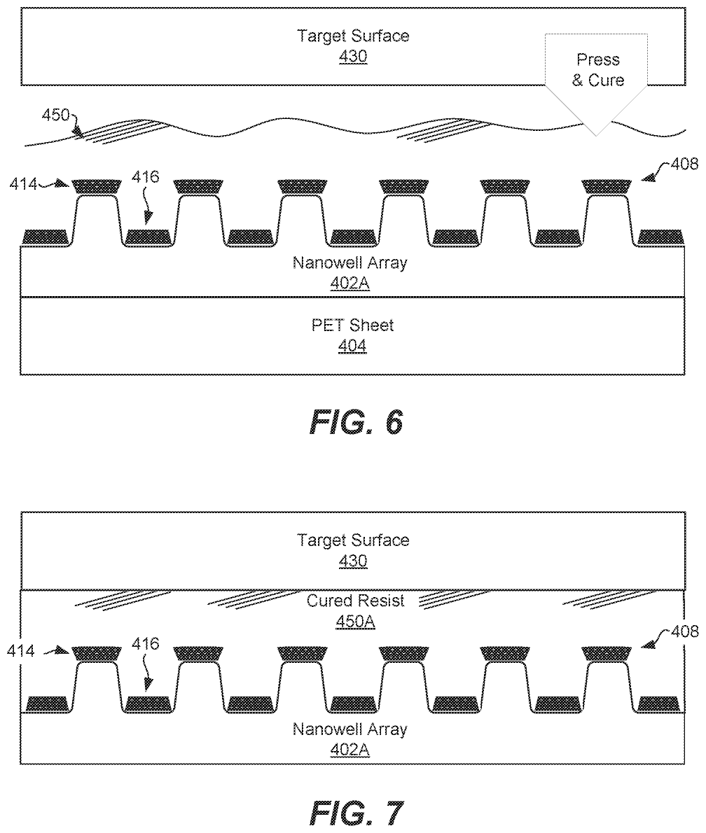

At step 208 in FIG. 3, the process includes pressing a hydrophobic UV-curable resist over the NLPC array using a target surface, and curing the UV-curable resist. The target surface can be embodied as a range of different materials or surfaces, such as a PAA sheet, a textile, a membrane, or another target surface. The target surface can help to provide mechanical stabilization for the flexible scaffold upon which the NLPC array 408 is transferred, as described below. An example target surface 430 is shown in FIG. 6. A hydrophobic UV-curable resist, such as hydrophobic PFPE, is squeezed and pressed between the target surface and the NIPC array. The hydrophobic PFPE can be Fluorolink® MD700, which is a UV-curable PFPE hydrophobic compound, for example, or a similar hydrophobic UV-curable PFPE. As one example, after the PFPE is applied over the NLPC array, and the underlying nanowell array, the PFPE can be cured by UV light for 3 minutes under 6 bar of pressure applied top-down on the PAA sheet. The target surface acts as a type of working stamp for the pressing. This can be followed by another round of UV curing for 3 minutes or another time under a vacuum, to the extent needed. Other curing or cross-linking approaches can be relied upon.

An example of hydrophobic UV-curable resist 450 being applied, pressed, and cured between the target surface 430 and the NLPC array 408 on the nanowell array 402A is shown in FIG. 6. After the resist 450 is cured, the PET sheet 404 can be removed from the structure by lift off. In other cases, the PET sheet 404 can be removed in earlier or later steps.

At step 210, the process includes dissolving the nanowell array 402A in a solvent, such as anisole or water. For example, the structure shown in FIG. 7 can be submerged in anisole or water, or such a solvent can be otherwise poured or spread over the structure. The solvent softens the nanowell array 402A. The nanowell array 402A can be softened until the UV-cured resist 450A and NLPC array 408 can be lifted off and separated from the nanowell array 402A. Successful transfer of the NLPC array 408 onto the UV-cured resist 450A scaffold can be achieved with good transfer yields at step 212, due to the solubility of the nanowell array 402A in anisole, water, or another suitable solvent based on the material (e.g., PMMA, PAA, etc.) from which it is formed. The solvent weakens the adhesion between the NLPC array 408 and the nanowell array 402A, to permit reliable release of the plasmonic nanostructures in the NLPC array 408 from the nanowell array 402A.

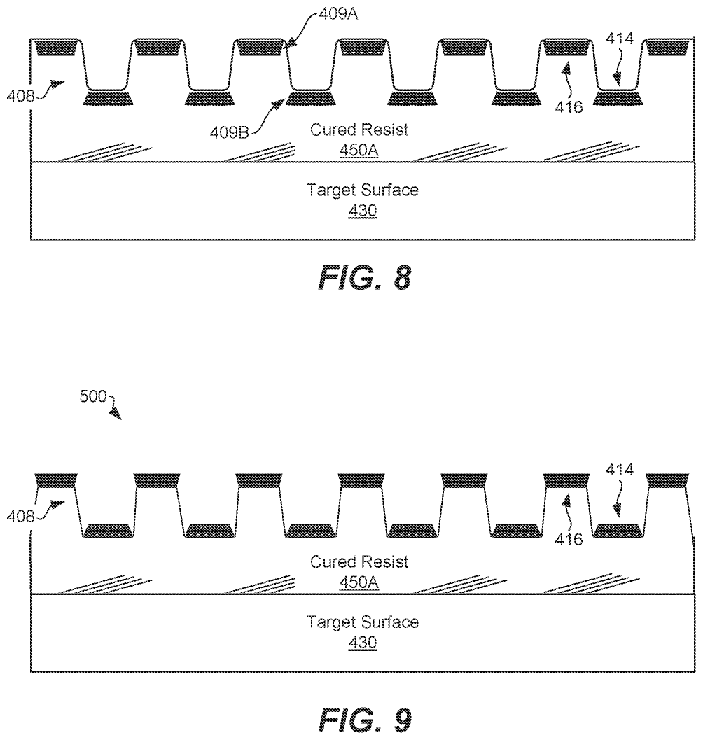

Step 210 effectively transfers the NLPC array 408 from the nanowell array 402A to the target surface through the UV-cured resist 450A, which is type of flexible scaffold that supports the NLPC array 408. Additionally, mechanically-stable plasmonic hotspot arrays are generated due to the strong bond between the UV-cured resist 450A and the NLPC array 408. The UV-cured resist 450A is one example of the scaffold 120 shown in FIG. 2A. An example of the resulting structure, which has been turned or rotated over as compared to FIG. 7, is shown in FIG. 8.

At step 212, the process includes etching the UV-cured resist 450A to expose the plasmonic nanogap hotspots of the NLPCs in the NLPC array 408. Example hotspots 409A and 409B are shown in FIG. 8, and the etching at step 214 can be performed to expose those and other hotspots in the NLPC array 408. As an example, reactive ion etching (RIE) can be used to remove a thin residual layer of the UV-cured resist 450A around the hotspots 409A and 409B, among others, in the NLPC array 408. A RIE plasma of oxygen and carbon tetrafluoride (CF₄) can be used, for example, to physically and chemically bombard the thin residual layer of the UV-cured resist 450A around the hotspots 409A and 409B.

The RIE etching time be tailored for surface-enhanced Raman spectroscopy (SERS) sensitivity or the sensitivity other plasmonic modes or enhancement techniques using the mechanically-stable plasmonic hotspot arrays described herein. In testing, an RIE etching time of 1 minute exhibited high SERS sensitivity (SERS EF=4.8×106) and good uniformity (RSD=9.0%) over a large area in one case. The RIE etching time of 1 minute exposed the embedded SERS hotspots while minimizing the structural deformation of the NLPCs resulting from RIE undercutting of the UV-cured resist 450A supporting the NLPCs. Other RIE etching times can be used, however, such as etching times between 30 seconds and 4 minutes, including all times between 30 seconds and 4 minutes in increments of 1 second. Additionally, partial etching of the insulating layers of the NLPCs in the NLPC array 408 can be performed using buffered oxide etch (BOE), to further open the hotspots. An example of the flexible NLPC array 500, after RIE and BOE etching to expose the hotspots, is shown in FIG. 9.

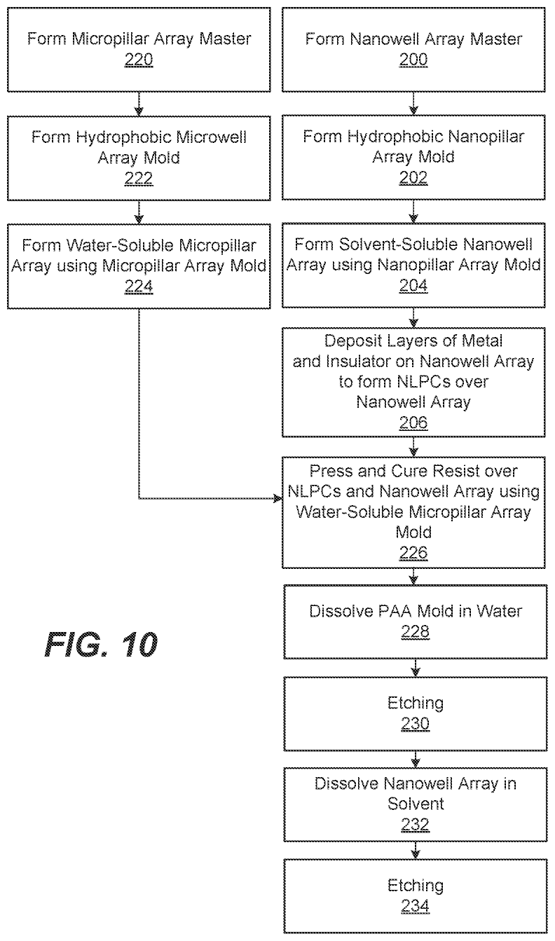

FIG. 10 illustrates an example method of fabricating MMPMs according to other aspects of the embodiments. The method includes a dissolvable template-based hierarchical imprinting approach. The particular sequence of steps illustrated in FIG. 10 can vary as compared to that shown. For example, one or more of the steps can be rearranged in order, one or more of the steps can be omitted, and one or more additional steps can be added to the process flow shown. Additionally, two or more of the steps can be performed concurrently or, at least in part, at the same time. Although the individual steps in FIG. 10 are described with reference to FIGS. 4-9 and 11-17 the illustrations in FIGS. 4-9 and 11-17 are only representative and the process can be applied to form other structures similar to those shown.

Steps 200, 202, 204, and 206 can be the same as or similar to those shown in FIG. 3. However, as compared to the method in FIG. 3, in which a flexible NLPC array is formed without pores, the method shown in FIG. 10 can be relied upon to form a flexible MMPM, such as the flexible MMPM 100 shown in FIG. 2A. Additionally, the process shown in FIG. 10 assumes that the nanowell array formed at step 204 is a solvent-soluble nanowell array, such as one formed from PMMA.

At step 220, the process includes forming a micropillar array master over a substrate from a photoresist using photolithography. For example, a two-dimensional array of micropillars composed of a photoresist can be formed on a silicon substrate via conventional photolithography. The photoresist can be a negative-tone photoresist, such as the SU8-2000.5 photoresist of KAYAKU® Advanced Materials Inc., although other photoresists can be relied upon. The photoresist can be spin coated over a silicon substrate, soft baked, and otherwise pre-processed for photolithography according to the recommended processing specifications for the photoresist. The resulting photoresist layer can then be patterned into a micropillar array by selective exposure to UV light and developed to form the micropillar array master over the substrate. The shapes and sizes of the individual micropillars can conform to the examples described above in FIGS. 2A and 2B, for the micropores 130-133, among others. The shapes and sizes of the individual micropillars in the micropillar array master will ultimately define the shapes and sizes of the micropores in the MMPMs formed using the process shown in FIG. 10

At step 222, the process includes forming a microwell array mold using the micropillar array master. The microwell array mold can be a hydrophobic microwell array mold. As one example, the microwell array mold can be formed from a UV-curable hydrophobic PFPE using UV nanoimprint lithography. To form the mold, the micropillar array master can be spin coated or drop dispensed with Fluorolink® MD700, which is a UV-curable PFPE hydrophobic compound, for example, or similar UV-curable hydrophobic PFPE. Imprinting the microwell array mold can then proceed by pressing the PFPE hydrophobic compound with a transparent template (e.g., a quartz glass or other working stamps), and the imprinted PFPE cured by UV-light exposure to cross-link the PFPE.

After it is applied and pressed over the micropillar array master, the PFPE can be cured by UV light for 3 minutes under 2 bar of pressure applied top-down on the working stamp. This can be followed by another round of UV curing for 3 minutes under a vacuum and a post-annealing step at 100° C. for 45 minutes, or other periods of time, to the extend needed. Other curing or cross-linking approaches can be relied upon. After curing, the hydrophobic microwell array mold can be lifted off the micropillar array master and used in later process steps.

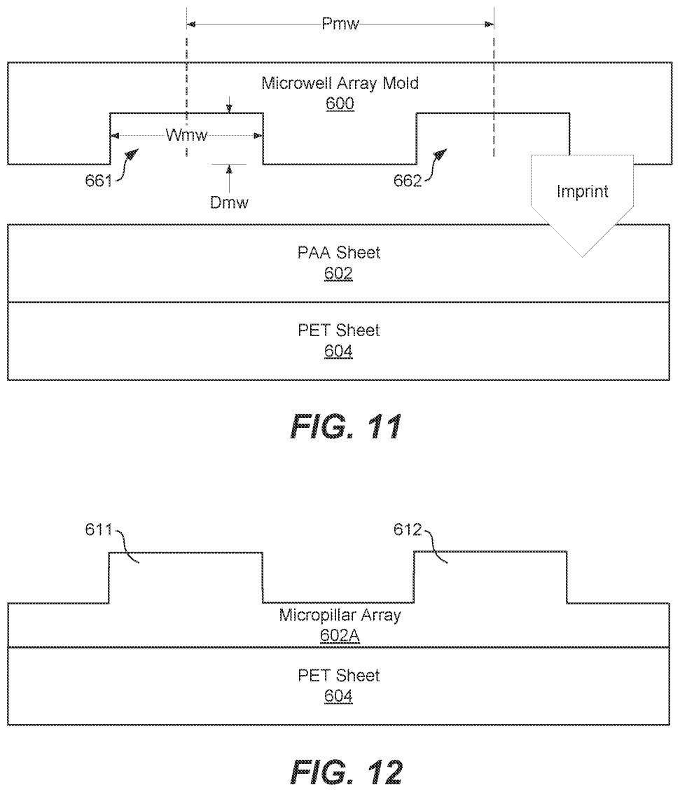

A cross-sectional view of a representative hydrophobic microwell array mold 600, formed in step 222, is illustrated in FIG. 11. The microwell array mold 600 is representative and not drawn to scale. Additionally, FIG. 11 only illustrates only a portion of the microwell array mold 600. The microwell array mold 600 includes a number of microwells, such as microwells 661 and 662, among others, in an array of microwell. The microwells are formed at a pitch “Pmw,” have a width “Wmw,” and have a depth “Dmw.” The pitch “Pmw,” width “Wmw,” and depth “Dmw” are determined by the pitch, width, and depth dimensions corresponding to the micropillars in the micropillar array master, as described above.

At step 224, the process includes forming a water-soluble micropillar array from PAA using the microwell array mold formed in step 222. First, a layer or sheet of water-soluble PAA is formed. As an example, a 50% w/w solution of PAA in methanol can be prepared and spin-coated on a sheet of PET over a substrate. The PET sheet can be relied upon as a transferring carrier for the PAA sheet. The PAA can have an average molecular weight of 1,800 g/mol, for example, although other types of PAA can be used. The PAA can be product number 323667 (CAS number 9003-01-4) of SIGMA-ALDRICH®, as one example. The solution of PAA in methanol can be spin coated on the sheet of PET at 3000 rpm, for 30 seconds, for example, followed by heating to evaporate the methanol solvent. An example PAA sheet 602 on a PET sheet 604 is shown in FIG. 11.

Next, the water-soluble micropillar array of PAA is formed by thermal nanoimprint lithography of the PAA sheet by the microwell array mold. Referring to FIG. 11 as an example, the microwell array mold 600 is imprinted (e.g., brought into contact with) into the PPA sheet 602. The microwell array mold 600 is pressed into the PAA sheet 602 under pressure and temperature. An example imprint time, pressure, and temperature are 3 mins, 6 bar, and 120° C., respectively, although other imprint times, pressures, and temperatures (e.g., temperatures above the glass transition temperature of the PAA) can be used. The microwell array mold 600 is then separated from the PAA sheet 602 (e.g., by lift off). The PAA sheet 602 is thus molded into a water-soluble micropillar array of PAA by the thermal nanoimprint lithography. An example micropillar array 602A of PAA on the PET sheet 604 is shown in FIG. 12. The micropillar array 602A includes pillars 611 and 612 of PAA, among others.

At step 226 in FIG. 10, the process includes pressing a hydrophobic UV-curable resist over the NLPC array formed on the nanowell array 402A at step 206, using the water-soluble micropillar array 602A of PAA formed at step 224 as a working stamp. Step 226 also includes curing the resist. A hydrophobic UV-curable resist, such as hydrophobic PFPE, is squeezed and pressed between the micropillar array 602A and the NLPC array. The hydrophobic PFPE can be Fluorolink® MD700, which is a UV-curable PFPE hydrophobic compound, for example, or a similar hydrophobic UV-curable PFPE. As one example, after the PFPE is applied over the NLPC array, and the underlying nanowell array, the PFPE can be cured by UV light for 3 minutes under 6 bar of pressure applied top-down on the micropillar array 602A of PAA. This can be followed by another round of UV curing for 3 minutes or another time under a vacuum, to the extent needed. Other curing or cross-linking approaches can be relied upon.

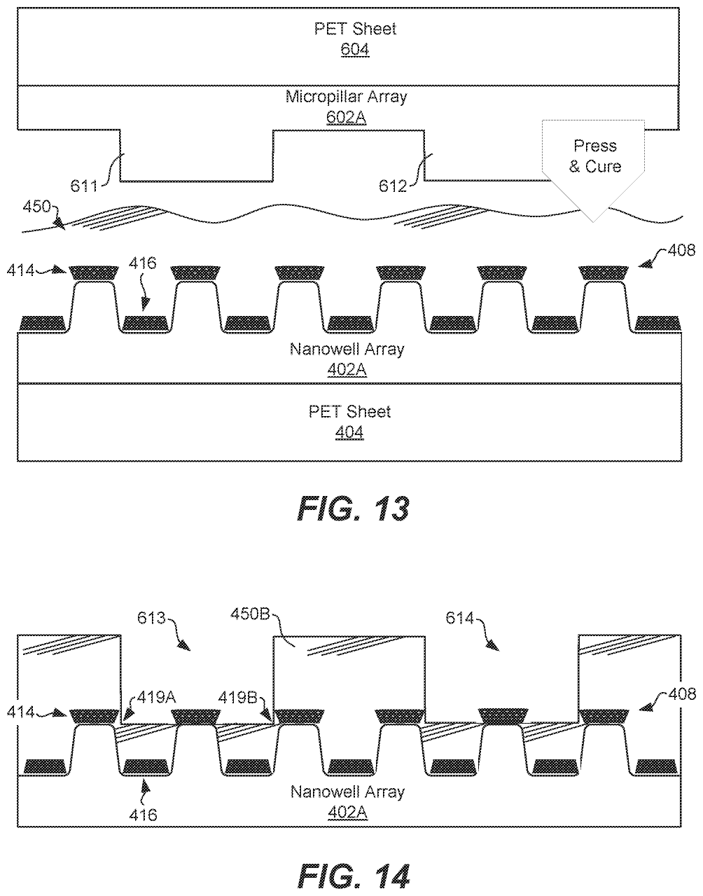

An example of hydrophobic UV-curable resist 450 being applied, pressed, and cured between the micropillar array 602A of PAA and the NLPC array 408 on the nanowell array 402A is shown in FIG. 13. Due to their wettability difference, the resist 450 can experience partial dewetting with the more hydrophilic micropillar array 602A of PAA and the NLPC-populated nanowell array 402A, which include micro/nano geometries to reduce the thickness of the residual layer. After the resist 450 is cured, the PET sheets 404 and 602 can be removed from the top and bottom of the structure by lift off. In other cases, the PET sheets 404 and 602 can be removed in earlier or later steps.

At step 228 in FIG. 10, the process includes dissolving the micropillar array 602A of PAA in water at a suitable temperature. For example, the structure can be submerged in water, such as water at 70° C. or another suitable temperature, until the micropillar array 602A of PAA is dissolved or dissolved to a suitable extent. An example of the resulting flexible, mechanically-stabilized NLPC array structure is shown in FIG. 14. The remaining structure includes the UV-cured resist 450B, the NLPC array 408, and the nanowell array 402A. The nanowell array 402A stabilizes the cured resist 450B and the NLPC array 408 for etching and other steps described below. Step 228 exposes a first micro-structured side of the UV-cured resist 450B, with the solvent-soluble nanowell array 402A remaining for support.

The solvent-soluble PMMA nanowell array 402A is water-insoluble. Thus, the nanowell array 402A remains attached to the UV-cured resist 450B, with the NLPC array 408 being intermediary between or among them. The UV-cured resist 450B is flexible, but the PMMA nanowell array 402A is more rigid and helps to keep the resulting structure flat and robust for handling, etching, and other purposes. As compared to the UV-cured resist 450A shown in FIG. 7, the UV-cured resist 450B includes voids 613 and 614, corresponding to the pillars 611 and 612 of the micropillar array 602A. The voids 613 and 614 ultimately form micropores in the resulting MMPM being formed, as sections of the UV-cured resist 450B become separated from other areas or sections, as described in further detail below.

At step 230 in FIG. 10, the process includes etching the UV-cured resist 450B from a first side (e.g., bottom side), to open micropores in the UV-cured resist 450B. For example, residual connections 419A and 419B in the UV-cured resist 450B, among others, are shown in FIG. 14, and the etching at step 230 can be performed to break those connections in the UV-cured resist 450B. RIE can be used to remove a thin residual layer of the UV-cured resist 450B at the connections 419A and 419B, among others. A RIE plasma of oxygen and CF₄ can be used, for example, to physically and chemically bombard the thin residual layer of the UV-cured resist 450B around the connections 419A and 419B. The etching separates regions of the UV-cured resist 450B from other regions and opens the micropores in the UV-cured resist 450B. The RIE etching time be tailored for opening the micropores, as needed.

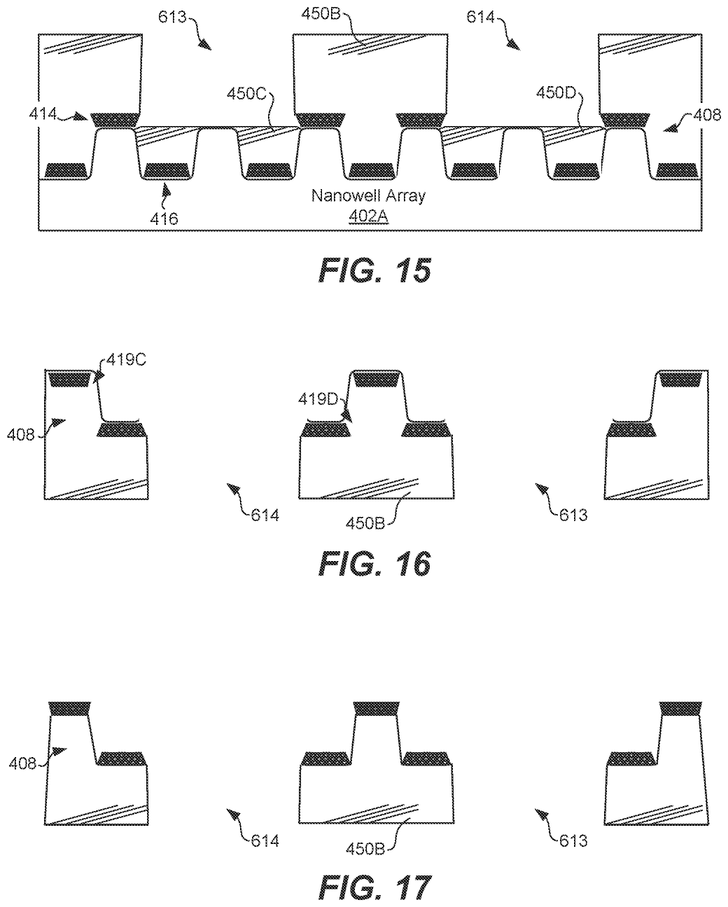

An example of the flexible, mechanically-stabilized NLPC array, after etching at step 230, is shown in FIG. 15. FIG. 15 is representative, however, and the etching at step 230 can remove more UV-cured resist, as well as some nanostructures of the NLPC array 408 and part of the top surface of the nanowell array 402A (or even all of the nanowell array 402A) within the voids 613 and 614. FIG. 15 shows, in any case, how the region of resist 450B is separated from the regions of resist 450C and 450D, as an example. The region of resist 450B is thus a continuous flexible scaffold having micropores at the positions of the voids 613 and 614, similar to the scaffold 120 shown in FIG. 2A.

At step 232 in FIG. 10, the process includes dissolving the nanowell array 402A in a solvent, such as anisole. For example, the structure shown in FIG. 15 can be submerged in anisole, or anisole can be otherwise poured or spread over the structure. The solvent softens the solvent-soluble PMMA nanowell array 402A. The nanowell array 402A can be softened until the UV-cured resist 450B and NLPC array 408 can be lifted off and separated from the nanowell array 402A and the regions of resist 450C and 450D. Successful transfer of the NLPC array 408 onto the UV-cured resist 450B scaffold can be achieved with good transfer yields at step 232, due to the solvent-solubility of the PMMA nanowell array 402A. The anisole solvent weakens the adhesion between the NLPC array 408 and the nanowell array 402A, to permit reliable release of the plasmonic nanostructures in the NLPC array 408 from the nanowell array 402A.

Step 232 effectively transfers the NLPC array 408 from the nanowell array 402A to the UV-cured resist 450B, which is type of flexible scaffold with micropores that supports the NLPC array 408. Additionally, mechanically-stable plasmonic hotspot arrays are generated due to the strong bond between the UV-cured resist 450B and the NLPC array 408. The UV-cured resist 450B is one example of the scaffold 120 shown in FIG. 2A. An example of the resulting flexible MMPM, which has been turned or rotated over as compared to FIG. 15, is shown in FIG. 16.

At step 234 in FIG. 10, the process includes further etching the UV-cured resist 450B from a second side (e.g., top side), to further expose the plasmonic nanogap hotspots of the NLPCs in the NLPC array 408. Example hotspots 419C and 419D are shown in FIG. 16, and the etching at step 234 can be performed to expose those and other hotspots in the NLPC array 408. RIE can be used to remove a thin residual layer of the UV-cured resist 450B around the hotspots 419C and 419D, among others, in the NLPC array 408. A RIE plasma of oxygen and CF₄ can be used, for example, to physically and chemically bombard the thin residual layer of the UV-cured resist 450B around the hotspots 419C and 419D.

The RIE etching time be tailored for SERS sensitivity or the sensitivity other plasmonic modes or enhancement techniques using the mechanically-stable plasmonic hotspot arrays described herein. In testing, an RIE etching time of 1 minute exhibited high SERS sensitivity and good uniformity over a large area in one case, although other etching times can be used. Additionally, partial etching of the insulating layers of the NLPCs in the NLPC array 408 can be performed using BOE, to further open the hotspots. An example of the flexible, mechanically-stabilized NLPC array, after RIE and BOE etching to expose the hotspots, is shown in FIG. 17.

The fabrication processes described herein reply upon a number of new techniques or approaches, including (1) partial detwetting of a hydrophobic, UV curable resist with hydrophilic micro/nano structured templates to minimize the residual layer thickness during imprinting, (2) solvent-solubility of the nano-structured template enabling the transfer of the NLPCs onto polymeric scaffolds with excellent transfer yield, (3) hierarchical solubility of the micro- and nano-structured templates enabling the uniform and user-friendly RIE etching processing for reproducibly eliminating the polymeric residual layer, (4) strong bonding between the UV-cured polymeric scaffold and the NLPCs generating mechanically stable plasmonic hotspot arrays, and (5) mild processing steps with low-toxicity solvents at low temperature thus allowing manufacturing compatibility with UV-curable polymers.

The biomechanical properties, such as relatively low bending stiffness (e.g., as compared to other biological systems), and high permeability to nutrients and oxygen, of the biomimetic polymeric scaffolds coupled with the multi-resonant plasmonic capabilities of the NLPCs enable active monitoring or actuation of biological activities in living systems with unique biocompatibility benefits.

Additionally, the MMPMs described herein can serve as broadband nonlinear nanoplasmonic devices to generate SHG, THG, and UCPL upconversion signals under fs pulse excitation, opening avenues for bio-interfaced nonlinear optical sensing and imaging applications. The MMPMs can function as bio-interfaced SERS mesh sensors for in-situ spatiotemporal SERS molecular profiling of bacterial biofilm activities. The biomechanical compatibility and transport permeability of microporous ultrathin polymeric meshes coupled with the multi-resonant plasmonic capabilities of the NLPC hotspot arrays in the MMPMs can potentially open the door for various bio-interfaced optical sensing and actuation applications such as inflammation-free epidermal sensors in conformal contact with skin, combined tissue-engineering and biosensing scaffolds for in-vitro 3D cell culture models, and minimally invasive implantable probes for long-term disease diagnostics and therapeutics.

The features, structures, or characteristics described above may be combined in one or more embodiments in any suitable manner, and the features discussed in the various embodiments are interchangeable, if possible. In the foregoing description, numerous specific details are provided in order to fully understand the embodiments of the present disclosure. However, a person skilled in the art will appreciate that the technical solution of the present disclosure may be practiced without one or more of the specific details, or other methods, components, materials, and the like may be employed. In other instances, well-known structures, materials, or operations are not shown or described in detail to avoid obscuring aspects of the present disclosure.

Although relative terms such as “above,” “below,” “upper,” “lower,” “top,” “bottom,” “right,” “left,” “input,” and “output” may be used to describe the relative spatial relationships of certain components or structural features, the terms are used for convenience in the examples. It should be understood that if a device or component is turned upside down, the “upper” component will become a “lower” component. When a structure or feature is described as being “on” (or formed on) another structure or feature, the structure can be positioned directly on (i.e., contacting) the other structure, without any other structures or features intervening between the structure and the other structure. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified. The terms “first,” “second,” etc. are used as distinguishing labels in some cases, rather than a limitation of the number of the objects, unless otherwise specified.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

1. A method of manufacture of a flexible microporous multi-resonant plasmonics mesh (MMPM), comprising:
depositing alternating metal and insulating layers on a solvent-soluble nanowell array, to form a nanolaminate plasmonic crystal (NLPC) array on the solvent-soluble nanowell array;
pressing a hydrophobic curable resist over the NLPC array and the solvent-soluble nanowell array, using a water-soluble micropillar array as a working stamp for the pressing;
curing the hydrophobic curable resist into a flexible scaffold;
dissolving the water-soluble micropillar array in water, to expose a first side of the flexible scaffold, with the solvent-soluble nanowell array supporting a second side of the flexible scaffold;
dissolving the solvent-soluble nanowell array in a solvent; and
separating the solvent-soluble nanowell array from the NLPC array and the flexible scaffold.

2. The method of claim 1, further comprising:
forming a micropillar array master over a substrate with a photoresist using photolithography;
forming a hydrophobic microwell array mold from hydrophobic perfluoropolyether (PFPE) using the micropillar array master; and
forming the water-soluble micropillar array from polyacrylic acid (PAA) using the hydrophobic microwell array mold.

3. The method of claim 1, further comprising:
forming a nanowell array master in silicon;
forming a hydrophobic nanopillar array mold from hydrophobic perfluoropolyether (PFPE) using the nanowell array master; and
forming the solvent-soluble nanowell array from poly (methyl methacrylate) (PMMA) using the hydrophobic nanopillar array mold.

4. The method of claim 1, wherein the solvent comprises anisole.

5. The method of claim 1, further comprising etching flexible scaffold to expose plasmonic nanogap hotspots of NLPCs in the NLPC array.

6. The method of claim 5, wherein the etching comprises reactive ion etching (RIE) in a plasma of oxygen and carbon tetrafluoride (CF₄).

7. The method of claim 5, wherein the etching comprises buffered oxide etching.

8. The method of claim 1, further comprising forming voids in the hydrophobic curable resist during the pressing, with pillars of the water-soluble micropillar array.

9. The method of claim 8, wherein the voids open to micropores in the NLPC array and the flexible scaffold, after the dissolving and the separating.

10. The method of claim 1, wherein depositing the alternating metal and insulating layers comprises depositing alternating layers of gold and silicon dioxide.

11. A flexible microporous multi-resonant plasmonics mesh (MMPM), comprising:
a flexible scaffold;
a nanolaminate plasmonic crystal (NLPC) array on the flexible scaffold; and
micropores extending through the flexible scaffold and the NLPC array.

12. The flexible MMPM according to claim 11, wherein the flexible scaffold comprises a UV-cured hydrophobic resist.

13. The flexible MMPM according to claim 11, wherein the micropores comprise a periodic array of micropores.

14. The flexible MMPM according to claim 11, wherein the micropores comprise a shape other than a four-sided shape.

15. The flexible MMPM according to claim 11, wherein the NLPC array comprises a two-tier NLPC array.

16. A method of manufacture of a flexible multi-resonant plasmonics array, comprising:
depositing alternating metal and insulating layers on a nanowell array, to form a nanolaminate plasmonic crystal (NLPC) array on the nanowell array;
pressing a hydrophobic curable resist over the NLPC array and the nanowell array, using a target surface;
curing the hydrophobic curable resist into a flexible scaffold;
dissolving the solvent-soluble nanowell array in a solvent; and
separating the nanowell array from the NLPC array and the target surface.

17. The method of claim 16, further comprising:
forming a nanowell array master in silicon;
forming a hydrophobic nanopillar array mold from hydrophobic perfluoropolyether (PFPE) using the nanowell array master; and
forming the nanowell array from poly(methyl methacrylate) (PMMA) or polyacrylic acid (PAA) using the hydrophobic nanopillar array mold.

18. The method of claim 16, further comprising etching the flexible scaffold to expose plasmonic nanogap hotspots of NLPCs in the NLPC array.

19. The method of claim 18, wherein the etching comprises reactive ion etching (RIE) in a plasma of oxygen and carbon tetrafluoride (CF₄) and etching with buffered oxide.

20. The method of claim 16, wherein the target surface comprises a textile or a membrane.
